(19) United States
(12) Patent Application Publication
(10) Pub. No.: US 2010/0139851 A1
(43) Pub. Date: Jun. 10, 2010

(54) Carbon nanotube heater

(75) Inventors: Chen Feng, Beijing (CN); Kai Liu, Beijing (CN); Ding Wang, Beijing (CN); Kai-Li Jiang, Beijing (CN); Chang-Hong Liu, Beijing (CN); Shou-Shan Fan, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: Tsinghua University, Beijing City (CN); HON HAI Precision Industry CO., LTD., Tu-Cheng City (TW)

(21) Appl. No.: 12/462,188

(22) Filed: Jul. 30, 2009

Related U.S. Application Data
(63) Continuation of application No. 12/456,071, filed on Jun. 11, 2009.

(30) Foreign Application Priority Data
Jun. 13, 2008 (CN) 200810067731.2
Jun. 18, 2008 (CN) 200810067904.0
Jun. 27, 2008 (CN) 200810068069.2
Jun. 27, 2008 (CN) 200810068070.5
Jun. 27, 2008 (CN) 200810068076.2
Jun. 27, 2008 (CN) 200810068077.7
Jun. 27, 2008 (CN) 200810068078.1
Jul. 11, 2008 (CN) 200810068458.5
Jul. 11, 2008 (CN) 200810068459.X
Jul. 11, 2008 (CN) 200810068461.7
Jul. 11, 2008 (CN) 200810068462.1
Jul. 25, 2008 (CN) 200810142522.X
Jul. 25, 2008 (CN) 200810142526.8
Jul. 25, 2008 (CN) 200810142527.2
Jul. 25, 2008 (CN) 200810142528.7
Jul. 25, 2008 (CN) 200810142529.1
Jul. 25, 2008 (CN) 200810142610.X
Jul. 25, 2008 (CN) 200810142614.8
Jul. 25, 2008 (CN) 200810142615.2
Jul. 25, 2008 (CN) 200810142616.7
Jul. 25, 2008 (CN) 200810142617.1

(51) Int. Cl. C23C 14/34; B29C 65/48; B29C 65/56; C23C 14/46; B32B 37/00; B32B 37/12; B29C 55/00; B29C 43/10; B29B 15/00; C01B 31/02; D01F 9/12; H01R 43/20

(52) U.S. Cl. 156/242; 156/296; 204/192.11; 204/192.1; 264/164; 264/341; 264/319; 264/109; 264/232; 29/876; 977/742; 977/842

(57) ABSTRACT

A method for making a heater is provided. A carbon nanotube structure is made, and a first electrode and a second electrode are provided. The first and second electrodes are electrically connected to the carbon nanotube structure.

### BACKGROUND

1. Technical Field

The present disclosure generally relates to heaters based on carbon nanotubes.

2. Description of Related Art

Heaters are configured for generating heat. According to the structures, the heaters can be divided into three types: linear heater, planar heater and hollow heater.

The linear heater has a linear structure, and is a one-dimensional structure. An object to be heated can be wrapped by linear heater when the linear heater is used to heat the object. The linear heater has an advantage of being very small in size and can be used in appropriate applications.

The planar heater has a planar two-dimensional structure. An object to be heated is placed near the planar structure and heated. The planar heater provides a wide planar heating surface and an even heating to an object. The planar heater has been widely used in various applications such as infrared therapeutic instruments, electric heaters, etc.

The hollow heater defines a hollow space therein, and is three-dimensional structure. An object to be heated can be placed in the hollow space in a hollow heater. The hollow heater can apply heat in all directions about an object and will have a high heating efficiency. Hollow heaters have been widely used in various applications.

A typical heater includes a heating element and at least two electrodes. The heating element is located on the two electrodes. The heating element generates heat when a voltage is applied to it. The heating element is often made of metal such as tungsten. Metals, which have good conductivity, can generate a lot of heat even when a low voltage is applied. However, metals may be easily oxidized, thus the heater element has short life. Furthermore, since metals have a relative high density, metal heating elements are heavy, which limits applications of such a heater. Additionally, metal heating elements are difficult to bend to desired shapes without breaking.

What is needed, therefore, is a heater based on carbon nanotubes that can overcome the above-described shortcomings.

### BRIEF DESCRIPTION OF THE DRAWINGS

Many aspects of the present heater can better be understood with reference to the following drawings. The components in the drawings are not necessarily to scale, the emphasis instead being placed upon clearly illustrating the principles of the present heater.

FIG. 1 is an isotropic view of a planar heater having a carbon nanotube structure.

FIG. 2 is a schematic, cross-sectional view, along a line II-II of FIG. 1.

FIG. 3 is a Scanning Electron Microscope (SEM) image of a drawn carbon nanotube film.

FIG. 4 is a schematic of a carbon nanotube segment in the drawn carbon nanotube film of FIG. 3.

FIG. 5 is a SEM image of a flocculated carbon nanotube film.

FIG. 6 is a Scanning Electron Microscope (SEM) image of a pressed carbon nanotube film.

FIG. 7 is a Scanning Electron Microscope (SEM) image of an untwisted carbon nanotube wire.

FIG. 8 is a Scanning Electron Microscope (SEM) image of a twisted carbon nanotube wire.

FIG. 9 is an isotropic view of a hollow heater having a carbon nanotube structure.

FIG. 10 is a schematic, cross-sectional view, along a line X-X of FIG. 9.

FIG. 11 is an isotropic view of a hollow heater, wherein the heating element is a linear carbon nanotube structure.

FIG. 12 is an isotropic view of a hollow heater, wherein the heating element includes a plurality of parallel linear carbon nanotube structures.

FIG. 13 is an isotropic view of a hollow heater, wherein the heating element includes a plurality of woven linear carbon nanotube structures.

FIG. 14 is a flow chart of a method for fabricating the hollow heater.

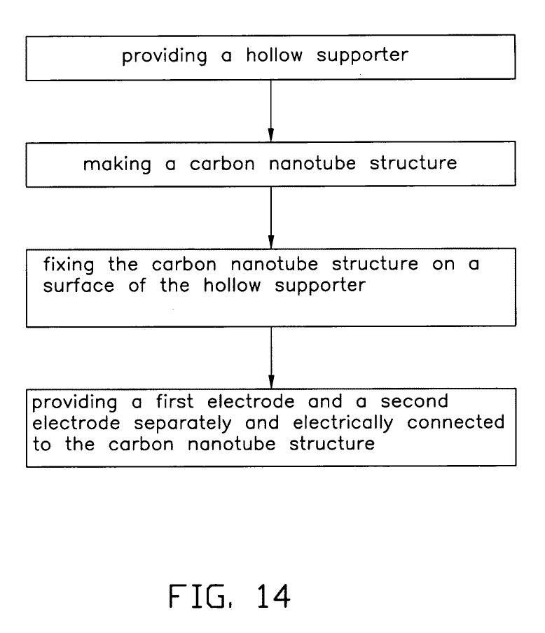

FIG. 15 is a schematic, cross-sectional view of a linear heater according to an embodiment.

FIG. 16 is a schematic, cross-sectional view, along a line XVI-XVI of FIG. 15.

FIG. 17 is a flow chart of a method for fabricating the linear heater.

Corresponding reference characters indicate corresponding parts throughout the several views. The exemplifications set out herein illustrate at least one exemplary embodiment of the present heater, in at least one form, and such exemplifications are not to be construed as limiting the scope of the invention in any manner.

### DETAILED DESCRIPTION

Reference will now be made to the drawings, in detail, to describe embodiments of the heater.

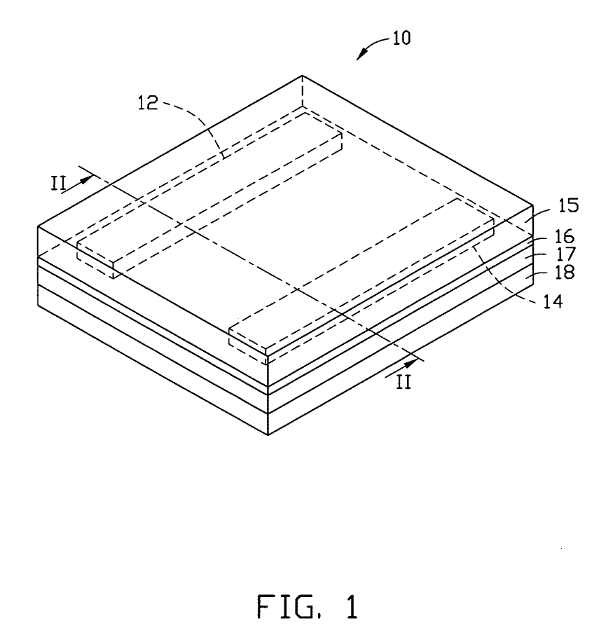

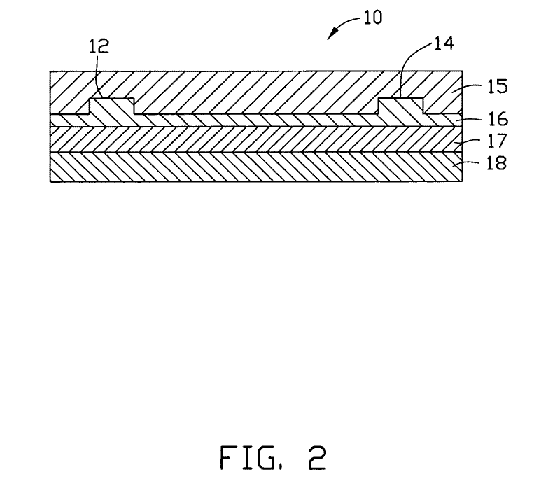

Referring to FIGS. 1 and 2, the planar heater 10 according to an embodiment is shown. The planar heater 10 includes a planar supporter 18, a heat-reflecting layer 17, a heating element 16, a first electrode 12, a second electrode 14, and a protecting layer 15. The heat-reflecting layer 17 is disposed on a surface of the planar supporter 18. The heating element 16 is disposed on a surface of the heat-reflecting layer 17. The first electrode 12 and the second electrode 14 are electrically connected to the heating element 16. In one embodiment, the first electrode 12 and the second electrode 14 are located on the heating element 16.

The planar supporter 18 is configured for supporting the heating element 16 and the heat-reflecting layer 17. The planar supporter 18 is made of flexible materials or rigid materials. The flexible materials may be plastics, resins or fibers. The rigid materials may be ceramics, glasses, or quartzes. When flexible materials are used, the planar heater 10 can be shaped into a desired form. The shape and size of the planar supporter 18 can be determined according to practical needs. For example, the planar supporter 18 may be square, round or triangular. When the material of the planar supporter 18 is rigid, the heater 10 can maintain a fixed shape. In one embodiment, the planar supporter 18 is a square ceramic sheet about 1 mm thick. A planar supporter 18 is only used when desired. The heating element 16 can be free standing structure.

The heat-reflecting layer 17 is configured for reflecting the heat emitted by the heating element 16, and control the direction of heat from the heating element 16 for single-side heating. The heat-reflecting layer 17 may be made of insulative materials. The material of the heat-reflecting layer 17 can be selected from a group consisting of metal oxides, metal salts, and ceramics. In one embodiment, the heat-reflecting layer 17 is an aluminum oxide (Al₂O₃) film. A thickness of the heat-reflecting layer 17 can be in a range from about 100 μm to about 0.5 mm. In one embodiment, the thickness of the heat-reflecting layer 17 is about 0.1 mm. The heat-reflecting layer 17 can be sandwiched between the heating element 16 and the planar supporter 18. Alternatively, the heat-reflecting layer 17 can be omitted, and the heating element 16 can be located directly on the planar supporter 18 if used. In other embodiments, the heating element can be free standing without being attached to either a planar supporter 18 or a heat-reflecting layer 17. When there is no heat-reflecting layer, the planar heater 10 can be used for double-side heating.

The heating element 16 includes a carbon nanotube structure. The carbon nanotube structure includes a plurality of carbon nanotubes uniformly distributed therein, and the carbon nanotubes therein can be combined by van der Waals attractive force therebetween. The carbon nanotube structure can be a substantially pure structure of the carbon nanotubes, with few impurities. The carbon nanotubes can be used to form many different structures and provide a large specific surface area. The heat capacity per unit area of the carbon nanotube structure can be less than 2×10⁻⁴ J/m²·K. Typically, the heat capacity per unit area of the carbon nanotube structure is less than 1.7×10⁻⁶ J/m²·K. As the heat capacity of the carbon nanotube structure is very low, and the temperature of the heating element 16 can rise and fall quickly, which makes the heating element 16 have a high heating efficiency and accuracy. As the carbon nanotube structure can be substantially pure, the carbon nanotubes are not easily oxidized and the life of the heating element 16 will be relatively long. Further, the carbon nanotubes have a low density, about 1.35 g/cm³, so the heating element 16 is light. As the heat capacity of the carbon nanotube structure is very low, the heating element 16 has a high response heating speed. As the carbon nanotube has large specific surface area, the carbon nanotube structure with a plurality of carbon nanotubes has large specific surface area. When the specific surface of the carbon nanotube structure is large enough, the carbon nanotube structure is adhesive and can be directly applied to a surface.

The carbon nanotubes in the carbon nanotube structure can be arranged orderly or disorderly. The term ‘disordered carbon nanotube structure’ refers to a structure where the carbon nanotubes are arranged along many different directions, and the aligning directions of the carbon nanotubes are random. The number of the carbon nanotubes arranged along each different direction can be almost the same (e.g. uniformly disordered). The disordered carbon nanotube structure can be isotropic. The carbon nanotubes in the disordered carbon nanotube structure can be entangled with each other.

The carbon nanotube structure including ordered carbon nanotubes is an ordered carbon nanotube structure. The term ‘ordered carbon nanotube structure’ refers to a structure where the carbon nanotubes are arranged in a consistently systematic manner, e.g., the carbon nanotubes are arranged approximately along a same direction and/or have two or more sections within each of which the carbon nanotubes are arranged approximately along a same direction (different sections can have different directions). The carbon nanotubes in the carbon nanotube structure can be selected from a group consisting of single-walled, double-walled, and/or multi-walled carbon nanotubes.

The carbon nanotube structure can be a carbon nanotube film structure with a thickness ranging from about 0.5 nanometers to about 1 millimeter. The carbon nanotube film structure can include at least one carbon nanotube film. The carbon nanotube structure can also be a linear carbon nanotube structure with a diameter ranging from about 0.5 nanometers to about 1 millimeter. The carbon nanotube structure can also be a combination of the carbon nanotube film structure and the linear carbon nanotube structure. It is understood that any carbon nanotube structure described can be used with all embodiments. It is also understood that any carbon nanotube structure may or may not employ the use of a support structure.

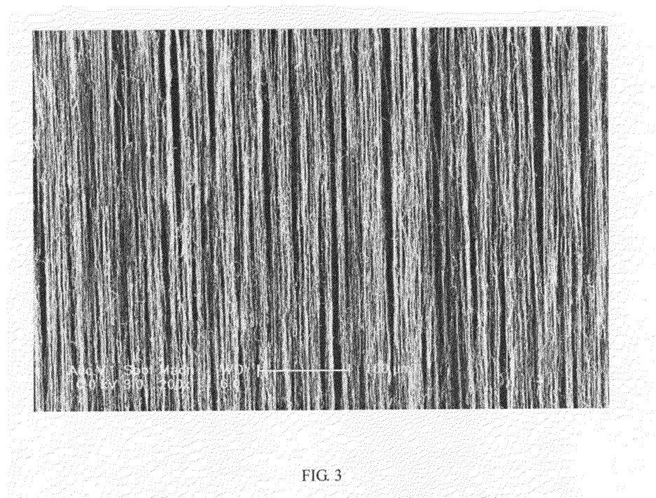

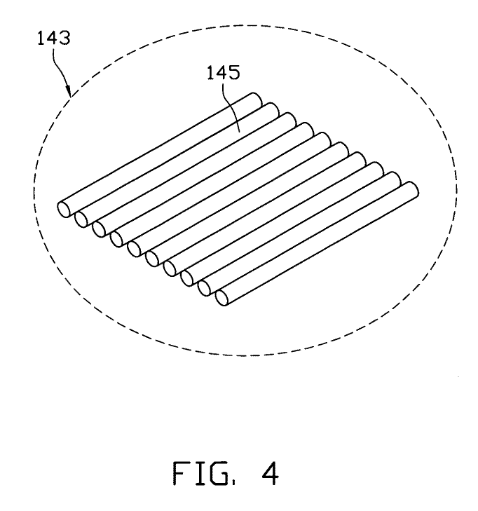

In one embodiment, the carbon nanotube film structure includes at least one drawn carbon nanotube film. A film can be drawn from a carbon nanotube array, to form a drawn carbon nanotube film. Examples of drawn carbon nanotube film are taught by U.S. Pat. No. 7,045,108 to Jiang et al., and WO 2007015710 to Zhang et al. The drawn carbon nanotube film includes a plurality of successive and oriented carbon nanotubes joined end-to-end by van der Waals attractive force therebetween. The drawn carbon nanotube film is a free-standing film. Referring to FIGS. 3 to 4, each drawn carbon nanotube film includes a plurality of successively oriented carbon nanotube segments 143 joined end-to-end by van der Waals attractive force therebetween. Each carbon nanotube segment 143 includes a plurality of carbon nanotubes 145 parallel to each other, and combined by van der Waals attractive force therebetween. As can be seen in FIG. 3, some variations can occur in the drawn carbon nanotube film. The carbon nanotubes 145 in the drawn carbon nanotube film are oriented along a preferred orientation. The carbon nanotube film can be treated with an organic solvent to increase the mechanical strength and toughness of the carbon nanotube film and reduce the coefficient of friction of the carbon nanotube film. A thickness of the carbon nanotube film can range from about 0.5 nanometers to about 100 micrometers.

The carbon nanotube film structure of the heating element 16 can include at least two stacked carbon nanotube films. In other embodiments, the carbon nanotube structure can include two or more coplanar carbon nanotube films, and can include layers of coplanar carbon nanotube films. Additionally, when the carbon nanotubes in the carbon nanotube film are aligned along one preferred orientation (e.g., the drawn carbon nanotube film), an angle can exist between the orientation of carbon nanotubes in adjacent films, whether stacked or adjacent. Adjacent carbon nanotube films can be combined by only the van der Waals attractive force therebetween. The number of the layers of the carbon nanotube films is not limited as long as the carbon nanotube structure. However the thicker the carbon nanotube structure, the specific surface area will decrease. An angle between the aligned directions of the carbon nanotubes in two adjacent carbon nanotube films can range from about 0° to about 90°. When the angle between the aligned directions of the carbon nanotubes in adjacent carbon nanotube films is larger than 0 degrees, a microporous structure is defined by the carbon nanotubes in the heating element 16. The carbon nanotube structure in an embodiment employing these films will have a plurality of micropores. Stacking the carbon nanotube films will also add to the structural integrity of the carbon nanotube structure. In some embodiments, the carbon nanotube structure has a free standing structure and does not require the use of the planar supporter 18.

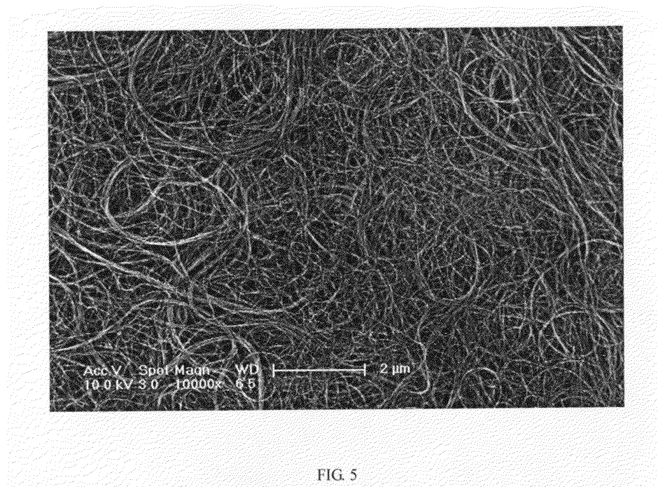

In another embodiment, the carbon nanotube film structure includes a flocculated carbon nanotube film. Referring to FIG. 5, the flocculated carbon nanotube film can include a plurality of long, curved, disordered carbon nanotubes entangled with each other. Further, the flocculated carbon nanotube film can be isotropic. The carbon nanotubes can be substantially uniformly dispersed in the carbon nanotube film. Adjacent carbon nanotubes are acted upon by van der Waals attractive force to form an entangled structure with micropores defined therein. It is understood that the flocculated carbon nanotube film is very porous. Sizes of the micropores can be less than 10 micrometers. The porous nature of the flocculated carbon nanotube film will increase specific surface area of the carbon nanotube structure. Further, due to the carbon nanotubes in the carbon nanotube structure being entangled with each other, the carbon nanotube structure employing the flocculated carbon nanotube film has excellent durability, and can be fashioned into desired shapes with a low risk to the integrity of the carbon nanotube structure. The flocculated carbon nanotube film, in some embodiments, will not require the use of the planar supporter 18 due to the carbon nanotubes being entangled and adhered together by van der Waals attractive force therebetween. The thickness of the flocculated carbon nanotube film can range from about 0.5 nanometers to about 1 millimeter.

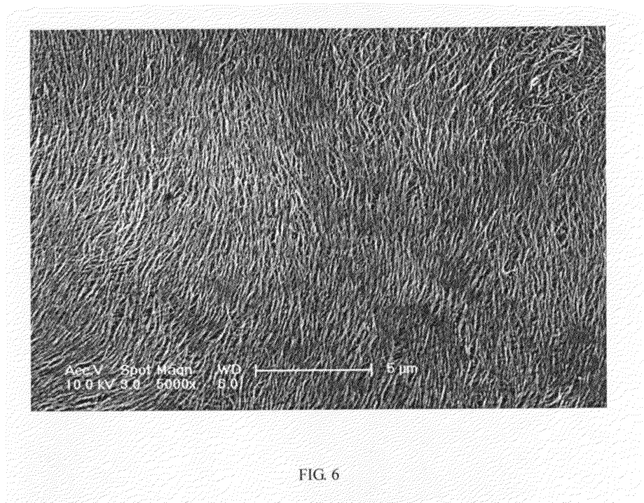

In another embodiment, the carbon nanotube film structure can include at least a pressed carbon nanotube film. Referring to FIG. 6, the pressed carbon nanotube film can be a free-standing carbon nanotube film. The carbon nanotubes in the pressed carbon nanotube film are arranged along a same direction or arranged along different directions. The carbon nanotubes in the pressed carbon nanotube film can rest upon each other. Adjacent carbon nanotubes are attracted to each other and combined by van der Waals attractive force. An angle between a primary alignment direction of the carbon nanotubes and a surface of the pressed carbon nanotube film is 0 degrees to approximately 15 degrees. The greater the pressure applied, the smaller the angle formed. When the carbon nanotubes in the pressed carbon nanotube film are arranged along different directions, the carbon nanotube structure can be isotropic. The thickness of the pressed carbon nanotube film ranges from about 0.5 nm to about 1 mm. Examples of pressed carbon nanotube film are taught by US application 20080299031A1 to Liu et al.

In other embodiments, the linear carbon nanotube structure includes carbon nanotube wires and/or carbon nanotube cables.

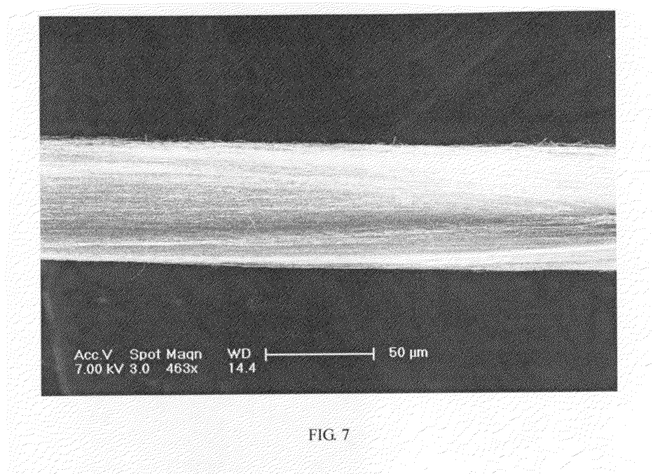

The carbon nanotube wire can be untwisted or twisted. Treating the drawn carbon nanotube film with a volatile organic solvent can form the untwisted carbon nanotube wire. Specifically, the organic solvent is applied to soak the entire surface of the drawn carbon nanotube film. During the soaking, adjacent parallel carbon nanotubes in the drawn carbon nanotube film will bundle together, due to the surface tension of the organic solvent as it volatilizes, and thus, the drawn carbon nanotube film will be shrunk into untwisted carbon nanotube wire. Referring to FIG. 7, the untwisted carbon nanotube wire includes a plurality of carbon nanotubes substantially oriented along a same direction (i.e., a direction along the length of the untwisted carbon nanotube wire). The carbon nanotubes are parallel to the axis of the untwisted carbon nanotube wire. More specifically, the untwisted carbon nanotube wire includes a plurality of successive carbon nanotube segments joined end to end by van der Waals attractive force therebetween. Each carbon nanotube segment includes a plurality of carbon nanotubes substantially parallel to each other, and combined by van der Waals attractive force therebetween. The carbon nanotube segments can vary in width, thickness, uniformity and shape. Length of the untwisted carbon nanotube wire can be arbitrarily set as desired. A diameter of the untwisted carbon nanotube wire ranges from about 0.5 nm to about 100 μm.

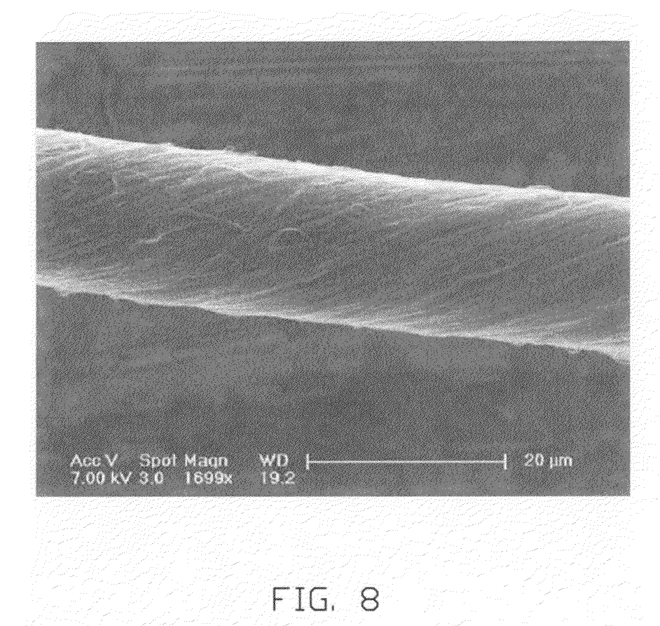

The twisted carbon nanotube wire can be formed by twisting a drawn carbon nanotube film using a mechanical force to turn the two ends of the drawn carbon nanotube film in opposite directions. Referring to FIG. 8, the twisted carbon nanotube wire includes a plurality of carbon nanotubes helically oriented around an axial direction of the twisted carbon nanotube wire. More specifically, the twisted carbon nanotube wire includes a plurality of successive carbon nanotube segments joined end to end by van der Waals attractive force therebetween. Each carbon nanotube segment includes a plurality of carbon nanotubes parallel to each other, and combined by van der Waals attractive force therebetween. Length of the carbon nanotube wire can be set as desired. A diameter of the twisted carbon nanotube wire can be from about 0.5 nanometers to about 100 micrometers. Further, the twisted carbon nanotube wire can be treated with a volatile organic solvent after being twisted. After being soaked by the organic solvent, the adjacent paralleled carbon nanotubes in the twisted carbon nanotube wire will bundle together, due to the surface tension of the organic solvent when the organic solvent volatilizing. The specific surface area of the twisted carbon nanotube wire will decrease, while the density and strength of the twisted carbon nanotube wire will be increased.

The carbon nanotube cable includes two or more carbon nanotube wires. The carbon nanotube wires in the carbon nanotube cable can be, twisted or untwisted. In an untwisted carbon nanotube cable, the carbon nanotube wires are parallel with each other. In a twisted carbon nanotube cable, the carbon nanotube wires are twisted with each other.

The heating element 16 can include a plurality of linear carbon nanotube structures. The plurality of linear carbon nanotube structures can be paralleled with each other, cross with each other, weaved together, or twisted with each other. The resulting structure can be a planar structure if so desired.

The first electrode 12 and the second electrode 14 can be disposed on a same surface or opposite surfaces of the heating element 16. Furthermore, it is imperative that the first electrode 12 be separated from the second electrode 14 to prevent short circuiting of the electrodes. The first electrode 12 and the second electrode 14 can be directly electrically attached to the heating element 16 by, for example, a conductive adhesive (not shown), such as silver adhesive. Because, some of the carbon nanotube structures have large specific surface area and are adhesive in nature, in some embodiments, the first electrode 12 and the second electrode 14 can be adhered directly to heating element 16. It should be noted that any other bonding ways may be adopted as long as the first electrode 12 and the second electrode 14 are electrically connected to the heating element 16. The shape of the first electrode 12 or the second electrode 14 is not limited and can be lamellar, rod, wire, and block among other shapes. In the embodiment shown in FIG. 1, the first electrode 12 and the second electrode 14 are both lamellar and parallel with each other. The material of the first electrode 12 and the second electrode 14 can be selected from metals, conductive resins, or any other suitable materials. In some embodiments, the carbon nanotubes in the heating element 16 are aligned along a direction perpendicular to the first electrode 12 and the second electrode 14. In other embodiments, at least one of the first electrode 12 and the second electrode 14 includes at least a carbon nanotube film or at least a linear carbon nanotube structure. In one embodiment, each of the first electrode 12 and the second electrode 14 includes a linear carbon nanotube structure. The linear carbon nanotube structures are separately disposed on the two ends of the heating element 16.

The protecting layer 15 is disposed on a surface of the heating element 16. In one embodiment, the protecting layer 15 fully covers a surface of the heating element 16. The protecting layer 15 and the heat-reflecting layer 17 are located at two opposite flanks of the heating element 16. The material of protecting layer 15 can be electric or insulative. The electric material can be metal or alloy. The insulative material can be resin, plastic or rubber. A thickness of the protecting layer 15 can range from about 0.5 μm to about 2 mm. When the material of the protecting layer 15 is insulative, the protecting layer 15 can electrically and/or thermally insulate the planar heater 10 from the external environment. The protecting layer 15 can also protect the heating element 16 from outside contaminants. The protecting layer 15 is an optional structure and can be omitted.

In use, when a voltage is applied to the first electrode 12 and the second electrode 14 of the planar heater 10, and the carbon nanotube structure of the heating element 16 radiates heat at a certain wavelength. The object to be heated can be directly attached on the planar heater 10 or separated from the planar heater 10. By controlling the specific surface area of the heating element 16, varying the voltage and the thickness of the heating element 16, the heating element 16 emits heat at different wavelengths. If the voltage is determined at a certain value, the wavelength of the electromagnetic waves emitted from the heating element 16 is inversely proportional to the thickness of the heating element 16. That is to say, the greater the thickness of heating element 16 is, the shorter the wavelength of the electromagnetic waves is. Further, if the thickness of the heating element 16 is determined at a certain value, the greater the voltage applied to the electrode, the shorter the wavelength of the electromagnetic waves. As such, the planar heater 10, can easily be controlled for emitting a visible light and create general thermal radiation or emit infrared radiation.

Further, due to carbon nanotubes having an ideal black body structure, the heating element 16 has excellent electrical conductivity, thermal stability, and high thermal radiation efficiency. The planar heater 10 can be safely exposed, while working, to oxidizing gases in a typical environment. The planar heater 10 can radiate an electromagnetic wave with a long wavelength when a voltage is applied on the planar heater 10. In one embodiment, the heating element 16 includes one hundred layers of drawn carbon nanotubes stacked on each other, and the orientation of the carbon nanotubes in the adjacent two carbon nanotubes are perpendicular with each other. Each drawn carbon nanotube film has a square shape with an area of 15 cm². A thickness of the carbon nanotube structure is about 10 μm. When the voltage ranges from 10 volts to 30 volts, the temperature of the planar heater 10 ranges from 50° C. to 500° C. As an ideal black body structure, the carbon nanotube structure 16 can radiate heat when it reaches a temperature of 200° C. to 450° C. The radiating efficiency is relatively high. Thus, the planar heater 10 can be used in electric heaters, infrared therapy devices, electric radiators, and other related devices.

Further, the planar heater 10 can be disposed in a vacuum device or a device with inert gas filled therein. When the voltage is increased in the approximate range from 80 volts to 150 volts, the planar heater 10 emits electromagnetic waves having a relatively short wave length such as visible light (e.g. red light, yellow light etc), general thermal radiation, and ultraviolet radiation. The temperature of the planar source 10 can reach 1500° C. When the voltage on the planar heater 10 is high enough, the planar heater 10 can eradiate ultraviolet to kill bacteria.

A method for making a planar heater 10 is disclosed. The method includes the steps of:

S1: providing a planar supporter 18;

S2: making a carbon nanotube structure;

S3: fixing the carbon nanotube structure on a surface of the planar supporter 18; and

S4: providing a first electrode 12 and a second electrode 14 separately and electrically connected to the carbon nanotube structure.

It is to be understood that, before step S3, an additional step of forming a heat-reflecting layer 17 attached to a surface of the planar supporter 18 can be performed. And the carbon nanotube structure is disposed on the surface of heat-reflecting layer 17, e.g. the heat-reflecting layer is located between the planar supporter 18 and the carbon nanotube structure. The heat-reflecting layer 17 can be formed by coating method, chemical deposition method, ion sputtering method, and so on. In one embodiment, the heat-reflecting layer 17 is a film made of aluminum oxide. The heat-reflecting layer 17 is coated to the heating element 16. After step S4, an additional step of forming a protecting layer 15 to cover the carbon nanotube structure can be carried out. The protecting layer 15 can be form by a sputtering method or a coating method.

In step S2, the carbon nanotube structure includes carbon nanotube films and linear carbon nanotube structures. The carbon nanotube films can be a drawn carbon nanotube film, a pressed carbon nanotube film or a flocculated carbon nanotube film, or a combination thereof.

In step S2, a method of making a drawn carbon nanotube film includes the steps of:

S21: providing an array of carbon nanotubes; and

S22: pulling out at least a drawn carbon nanotube film from the carbon nanotube array.

In step S21, a method of forming the array of carbon nanotubes includes:

S211: providing a substantially flat and smooth substrate;

S212: forming a catalyst layer on the substrate;

S213: annealing the substrate with the catalyst at a temperature in the approximate range of 700° C. to 900° C. in air for about 30 to 90 minutes;

S214: heating the substrate with the catalyst at a temperature in the approximate range from 500° C. to 740° C. in a furnace with a protective gas therein; and

S215: supplying a carbon source gas to the furnace for about 5 to 30 minutes and growing a super-aligned array of the carbon nanotubes from the substrate.

In step S211, the substrate can be a P or N-type silicon wafer. Quite suitably, a 4-inch P-type silicon wafer is used as the substrate.

In step S212, the catalyst can be made of iron (Fe), cobalt (Co), nickel (Ni), or any combination alloy thereof.

In step S214, the protective gas can be made up of at least one of nitrogen (N₂), ammonia (NH₃), and a noble gas.

In step S215, the carbon source gas can be a hydrocarbon gas, such as ethylene (C₂H₄), methane (CH₄), acetylene (C₂H₂), ethane (C₂H₆), or any combination thereof.

In step S22, a drawn carbon nanotube film can be formed by the steps of:

S221: selecting one or more carbon nanotubes having a predetermined width from the array of carbon nanotubes; and

S222: pulling the carbon nanotubes to form nanotube segments at an even/uniform speed to achieve a uniform carbon nanotube film.

In step S221, the carbon nanotube segment includes a plurality of parallel carbon nanotubes. The carbon nanotube segments can be selected by using an adhesive tape as the tool to contact the super-aligned array of carbon nanotubes. In step S222, the pulling direction is substantially perpendicular to the growing direction of the super-aligned array of carbon nanotubes.

More specifically, during the pulling process, as the initial carbon nanotube segments are drawn out, other carbon nanotube segments are also drawn out end to end due to van der Waals attractive force between ends of adjacent segments. This process of pulling produces a substantially continuous and uniform carbon nanotube film having a predetermined width can be formed.

After the step of S22, the drawn carbon nanotube film can be treated by applying organic solvent to the drawn carbon nanotube film to soak the entire surface of the carbon nanotube film. The organic solvent is volatile and can be selected from the group consisting of ethanol, methanol, acetone, dichloromethane, chloroform, any appropriate mixture thereof. In the one embodiment, the organic solvent is ethanol After being soaked by the organic solvent, adjacent carbon nanotubes in the carbon nanotube film that are able to do so, bundle together, due to the surface tension of the organic solvent when the organic solvent is volatilizing. In another aspect, due to the decrease of the specific surface area via bundling, the mechanical strength and toughness of the drawn carbon nanotube film are increased and the coefficient of friction of the carbon nanotube films is reduced. Macroscopically, the drawn carbon nanotube film will be an approximately uniform film.

The width of the drawn carbon nanotube film depends on a size of the carbon nanotube array. The length of the drawn carbon nanotube film can be set as desired. In one embodiment, when the substrate is a 4 inch type wafer as in the present embodiment, a width of the carbon nanotube film can be in an approximate range from 1 centimeter to 10 centimeters, a length of the carbon nanotube film can reach to about 120 m, a thickness of the drawn carbon nanotube film can be in an approximate range from 0.5 nanometers to 100 microns. Multiple films can be adhered together to form a film of any desired size.

In step S2, a method of making the pressed carbon nanotube film includes the following steps:

S21′: providing a carbon nanotube array and a pressing device; and

S22′: pressing the array of carbon nanotubes to form a pressed carbon nanotube film.

In step S21′, the carbon nanotube array can be made by the same method as S11.

In the step S22′, a certain pressure can be applied to the array of carbon nanotubes by the pressing device. In the process of pressing, the carbon nanotubes in the array of carbon nanotubes separate from the substrate and form the carbon nanotube film under pressure. The carbon nanotubes are substantially parallel to a surface of the carbon nanotube film.

In one embodiment, the pressing device can be a pressure head. The pressure head has a smooth surface. It is to be understood that, the shape of the pressure head and the pressing direction can determine the direction of the carbon nanotubes arranged therein. When a pressure head (e.g a roller) is used to travel across and press the array of carbon nanotubes along a predetermined single direction, a carbon nanotube film having a plurality of carbon nanotubes primarily aligned along a same direction is obtained. It can be understood that there may be some variation in the film. Different alignments can be achieved by applying the roller in different directions over an array. Variations on the film can also occur when the pressure head is used to travel across and press the array of carbon nanotubes several of times, variation will occur in the orientation of the nanotubes. Variations in pressure can also achieve different angles between the carbon nanotubes and the surface of the semiconducting layer on the same film. When a planar pressure head is used to press the array of carbon nanotubes along the direction perpendicular to the substrate, a carbon nanotube film having a plurality of carbon nanotubes isotropically arranged can be obtained. When a roller-shaped pressure head is used to press the array of carbon nanotubes along a certain direction, a carbon nanotube film having a plurality of carbon nanotubes aligned along the certain direction is obtained. When a roller-shaped pressure head is used to press the array of carbon nanotubes along different directions, a carbon nanotube film having a plurality of sections having carbon nanotubes aligned along different directions is obtained.

In step S2, the flocculated carbon nanotube film can be made by the following method:

S21″: providing a carbon nanotube array;

S22″: separating the array of carbon nanotubes from the substrate to get a plurality of carbon nanotubes;

S23″: adding the plurality of carbon nanotubes to a solvent to get a carbon nanotube floccule structure in the solvent; and

S24″: separating the carbon nanotube floccule structure from the solvent, and shaping the separated carbon nanotube floccule structure into a carbon nanotube film to achieve a flocculated carbon nanotube film.

In step S21″, the carbon nanotube array can be formed by the same method as step (a1).

In step S22″, the array of carbon nanotubes is scraped off the substrate to obtain a plurality of carbon nanotubes. The length of the carbon nanotubes can be above 10 microns.

In step S23″, the solvent can be selected from a group consisting of water and volatile organic solvent. After adding the plurality of carbon nanotubes to the solvent, a process of flocculating the carbon nanotubes can, suitably, be executed to create the carbon nanotube floccule structure. The process of flocculating the carbon nanotubes can be selected from the group consisting of ultrasonic dispersion of the carbon nanotubes and agitating the carbon nanotubes. In one embodiment ultrasonic dispersion is used to flocculate the solvent containing the carbon nanotubes for about 10-30 minutes. Due to the carbon nanotubes in the solvent having a large specific surface area and the tangled carbon nanotubes having a large van der Waals attractive force, the flocculated and tangled carbon nanotubes form a network structure (i.e., floccule structure).

In step S24″, the process of separating the floccule structure from the solvent includes the substeps of:

S24″1: filtering out the solvent to obtain the carbon nanotube floccule structure; and

S24″2: drying the carbon nanotube floccule structure to obtain the separated carbon nanotube floccule structure.

In step S24″1, the carbon nanotube floccule structure can be disposed in room temperature for a period of time to dry the organic solvent therein. The time of drying can be selected according to practical needs. The carbon nanotubes in the carbon nanotube floccule structure are tangled together.

In step S24″2, the process of shaping includes the substeps of:

S24″21: putting the separated carbon nanotube floccule structure into a container (not shown), and spreading the carbon nanotube floccule structure to form a predetermined structure;

S24″22: pressing the spread carbon nanotube floccule structure with a certain pressure to yield a desirable shape; and

S24″23: removing the residual solvent contained in the spread floccule structure to form the flocculated carbon nanotube film.

Through the flocculating, the carbon nanotubes are tangled together by van der Walls attractive force to form a network structure/floccule structure. Thus, the flocculated carbon nanotube film has good tensile strength. The flocculated carbon nanotube film includes a plurality of micropores formed by the disordered carbon nanotubes. A diameter of the micropores can be less than about 100 micron. As such, a specific area of the flocculated carbon nanotube film is extremely large. Additionally, the pressed carbon nanotube film is essentially free of a binder and includes a large amount of micropores. The method for making the flocculated carbon nanotube film is simple and can be used in mass production.

In step S2, a linear carbon nanotube structure includes carbon nanotube wires and/or carbon nanotube cables. The carbon nanotube wire can be made by the following steps:

S21′″: making a drawn carbon nanotube film; and

S22′″: treating the drawn carbon nanotube film to form a carbon nanotube wire.

In step S21′″, the method for making the drawn carbon nanotube film is the same the step S21.

In step S22′″, the drawn carbon nanotube film is treated with a organic solvent to form an untwisted carbon nanotube wire or is twisted by a mechanical force (e.g., a conventional spinning process) to form a twist carbon nanotube wire. The organic solvent is volatilizable and can be selected from the group consisting of ethanol, methanol, acetone, dichloroethane, and chloroform. After soaking in the organic solvent, the carbon nanotube segments in the carbon nanotube film can at least partially bundle into the untwisted carbon nanotube wire due to the surface tension of the organic solvent.

It is to be understood that a narrow carbon nanotube film can serve as a wire. In this situation, through microscopically view, the carbon nanotube structure is a flat film, and through macroscopically view, the narrow carbon nanotube film would look like a long wire.

In step S2, the carbon nanotube cable can be made by bundling two or more carbon nanotube wires together. The carbon nanotube cable can be twisted or untwisted. In the untwisted carbon nanotube cable, the carbon nanotube wires are parallel with each other, and the carbon nanotubes can be kept together by an adhesive (not shown). In the twisted carbon nanotube cable, the carbon nanotube wires twisted with each other, and can be adhered together by an adhesive or a mechanical force.

In step S2, the drawn carbon nanotube film, the pressed carbon nanotube the flocculated carbon nanotube film, or the linear carbon nanotube structure can be overlapped, stacked with each other, and/or disposed side by side to make a carbon nanotube structure. It is also understood that this carbon nanotube structure can be employed by all embodiments.

In step S3, the carbon nanotube structure can be fixed on the surface of the planar supporter 18 with an adhesive or by a mechanical force.

In step S4, the first electrode 12 and the second electrode 14 are made of conductive materials, and formed on the surface of the heating element 16 by sputtering method or coating method. The first electrode 12 and the second electrode 14 can also be attached on the heating element 16 directly with a conductive adhesive or by a mechanical force. Further, silver paste can be applied on the surface of the heating element 16 directly to form the first electrode 12 and the second electrode 14.

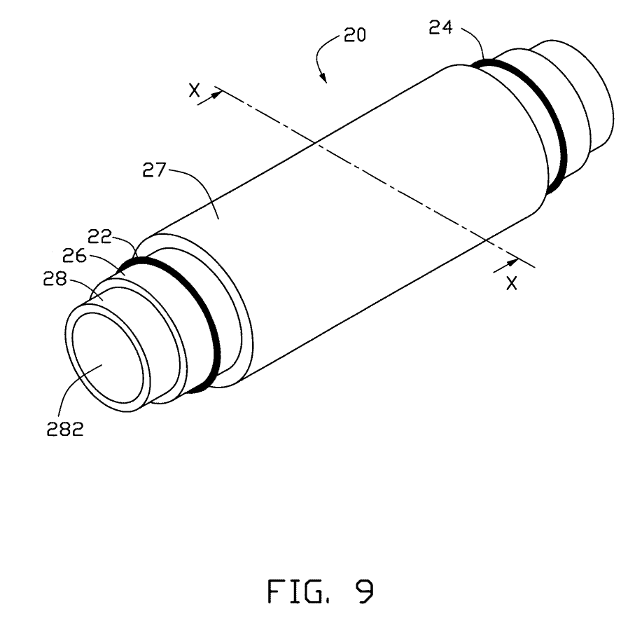

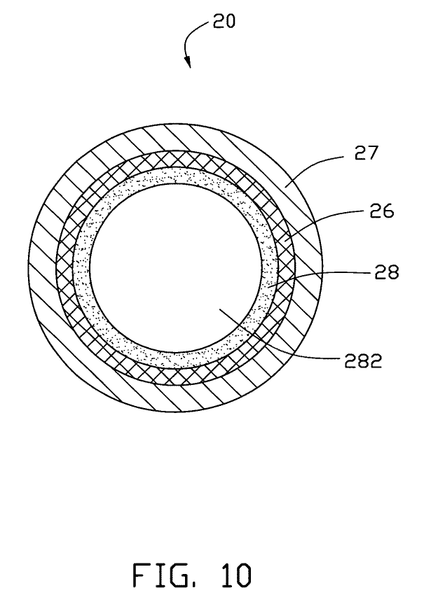

Referring to FIGS. 9 and 10, a hollow heater 20 is shown. The hollow heater 20 includes a hollow supporter 28, a heating element 26, a first electrode 22, a second electrode 24, and a heat-reflecting layer 27. The heating element 26 is disposed on an outer circumferential surface of the hollow supporter 28. The heat-reflecting layer 27 is disposed on an outer circumferential surface of the heating element 26. The hollow supporter 28 and the heat-reflecting layer 27 are located at two opposite circumferential surfaces of the heating element 26. The first electrode 22 and the second electrode 24 are electrically connected to the heating element 26 and spaced from each other. In one embodiment, the first electrode 22 and the second electrode 24 are located on opposite ends of the heat-reflecting layer 27.

The hollow supporter 28 is configured for supporting the heating element 22 and the heat-reflecting layer 27. The hollow supporter 28 defines a hollow space 282. The shape and size of the hollow supporter 28 can be determined according to practical demands. For example, the hollow supporter 28 can be shaped as a hollow cylinder, a hollow ball, or a hollow cube, for example. Other characters of the hollow supporter 28 are the same as the planar supporter 18 disclosed herein. In one embodiment, the hollow supporter 28 is a hollow cylinder.

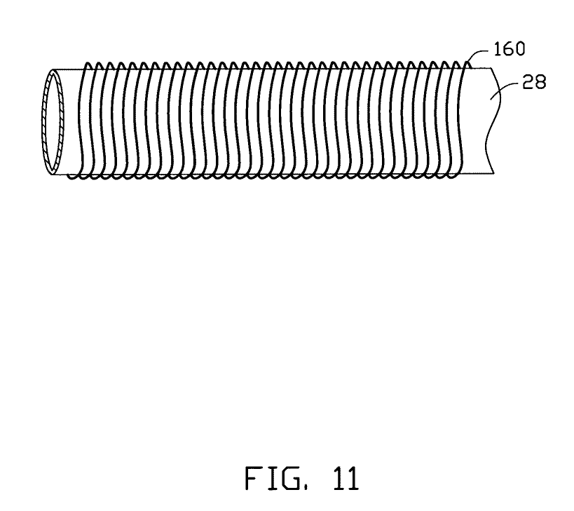

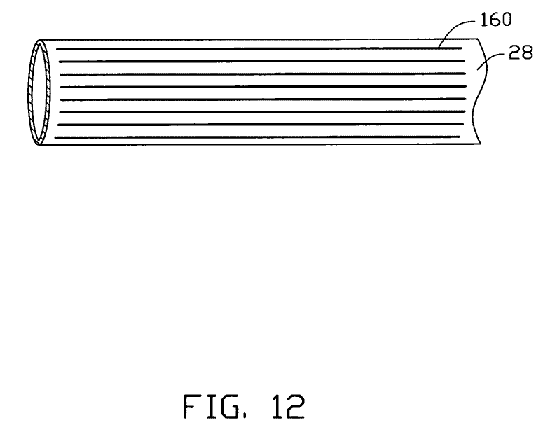

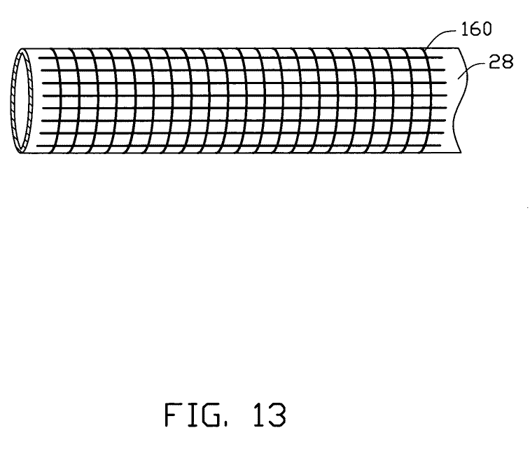

The heating element 26 can be attached on the inner surface or wrapped on the outer surface of the hollow supporter 28. In the embodiment shown in FIGS. 9 and 10, the heating element 26 is disposed on the outer circumferential surface of the hollow supporter 28. The heating element 26 can be fixed on the hollow supporter 28 with an adhesive (not shown) or by a mechanical force. The same as the heating element 16 discussed above, the heating element 26 includes a carbon nanotube structure. The characters of the carbon nanotube structure are the same as the carbon nanotube structure disclosed in the above. All embodiments of the carbon nanotube structure discussed above can be incorporated into the hallow heater 20. Same as disclosed herein, the carbon nanotube structure can be a carbon nanotube film structure, a linear carbon nanotube structure or a combination thereof. Referring to FIG. 11, the heating element 26 includes one linear carbon nanotube structure 160, the linear carbon nanotube structure 160 can twist about the hollow supporter 28 like a helix. In another example, referring to FIG. 12, when the heating element 26 includes two or more linear carbon nanotube structures 160, the linear carbon nanotube structures 160 can be disposed on the surface of the hollow supporter 28 and parallel with each other. The linear carbon nanotube structure can be disposed side by side or separately. In other examples, referring to FIG. 13, when the heating element 26 includes a plurality of linear carbon nanotube structures 160, the linear carbon nanotube structures 160 can be knitted to form a net disposed on the surface of the hollow supporter 28. It is understood that these linear carbon nanotube structures 160 can be applied to the inside of the supporter 28. It is understood that in some embodiments, some of the carbon nanotube structures have large specific surface area and adhesive nature, such that the heating element 26 can be adhered directly to surface of the hollow supporter 28.

The first electrode 22 and the second electrode 24 can be disposed on a same surface or opposite surfaces of the heating element 26. Furthermore, it is imperative that the first electrode 22 be separated from the second electrode 24 to prevent short circuiting of the electrodes. The first electrode 22 and the second electrode 24 can be the same as the first electrode 12 and the second electrode 14 discussed above. All embodiments of the electrodes discussed herein can be incorporated into the hollow heater 20. In the embodiment shown in FIG. 9, the first electrode 22 and the second electrode 24 are both wire ring surrounded the heating element 26 and parallel with each other. And each of the first electrode 22 and the second electrode 24 includes a linear carbon nanotube structure. The linear carbon nanotube structures disposed on the two ends of the heating element 26, and wrap the heating element 26 to form two wire rings.

The heat-reflecting layer 27 can be located on the inner surface of the hollow supporter 28, and the heating element 26 is disposed on the inner surface of the heat-reflecting layer 27. In a second example, the heat-reflecting layer 27 can be located on the outer surface of the hollow supporter 28, and the heating element 26 is disposed on the inner surface of the hollow supporter 28. Alternatively, the heat-reflecting layer 27 can be omitted. Without the heat-reflecting layer 27, the heating element 26 can be located directly on the hollow supporter 28. The other properties of the heat-reflecting layer 27 are the same as the heat-reflecting layer 17 discussed above.

When one of the inner circumferential and the outer circumferential surfaces of the heating element 26 is exposed to air, the hollow heater 20 can further include a protecting layer (not shown) attached to the exposed surface of the heating element 26. The protecting layer can protect the hollow heater 20 from the environment. The protecting layer can also protect the heating element 26 from impurities. In one embodiment, the heating element 26 is disposed between the hollow supporter 28 and the heat-reflecting layer 27, therefore a protecting layer would not necessarily be needed.

In use of the hollow heater 20, an object that will be heated can be disposed in the hollow space 282. When a voltage is applied to the first electrode 22 and the second electrode 24, the carbon nanotube structure of the heating element 26 of the hollow heater 20 generates heat. As the object is disposed in the hollow space 282, the whole body of the object can be heated equally.

A method for making a hollow heater 20 is disclosed. The method includes the steps of:

M1: providing a hollow supporter 28;

M2: making a carbon nanotube structure;

M3: fixing the carbon nanotube structure on a surface of the hollow supporter 28; and

M4: providing a first electrode 22 and a second electrode 24 and electrically connecting them to the carbon nanotube structure.

It is to be understood that, after step M3, additional step of forming a heat-reflecting layer 27 attached to the heating element 26 is provided. The heat-reflecting layer 27 can be formed by coating method, chemical deposition method, ion sputtering method, and so on. In one embodiment, the heat-reflecting layer 27 is a film made of aluminum oxide and is coated on the heating element 26.

In step M2, the detailed process of making the carbon nanotube structure is the same as the step S2 disclosed herein.

In step M3, the carbon nanotube structure can be fixed on an inner or an outer surface of the hollow supporter 28 with an adhesive or by mechanical method. In some embodiments, the carbon nanotube structure can be directly fixed on the hollow supporter directly because of the adhesive nature of the carbon nanotube structure. The carbon nanotube structure can wrap the outer surface of the hollow supporter 28.

The detail process of the step M4 can be the same as the step S4 in the first embodiment.

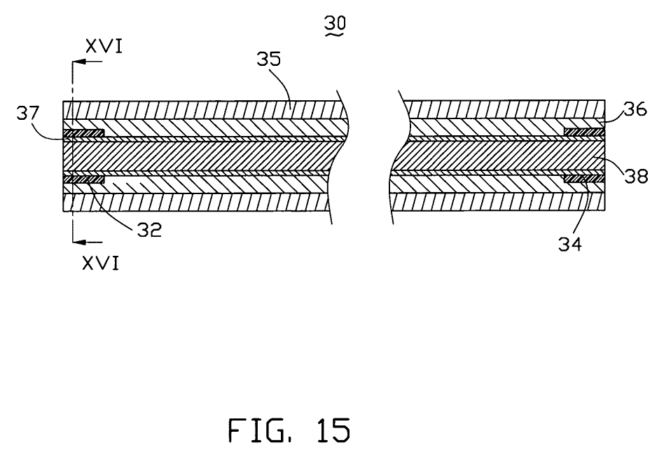

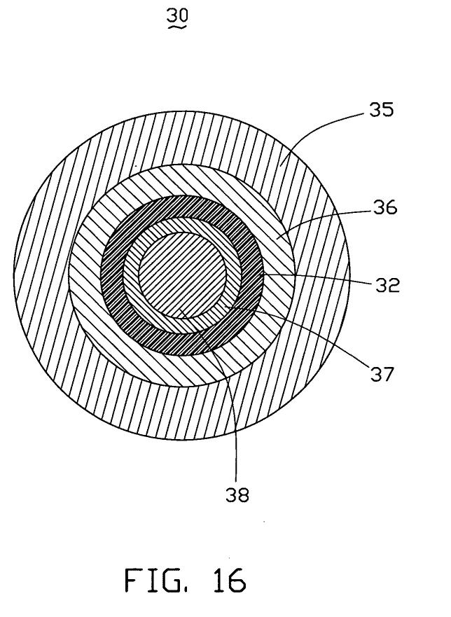

Referring FIGS. 15 and 16, a linear heater 30 is provided. The linear heater 30 includes a linear supporter 38, a reflecting layer 37, a heating element 36, a first electrode 32, a second electrode 34, and a protecting layer 35. The reflecting layer 37 is on the surface of the linear supporter 38; the heating element 36 wraps the surface of the reflecting layer 37. The first electrode 32 and the second electrode 34 are separately connected to the heating element 36. In one embodiment, the first electrode 32 and the second electrode 34 are located on the heating element 36. The protecting layer 35 covers the heating element 36, the first electrode 32 and the second electrode 34. A diameter of the linear heater 30 is very small compared with a length of itself. In one embodiment, the diameter of the linear heater 30 is in a range from about 1 μm to about 1 cm. A ratio of length to diameter of the linear heater 30 can be in a range from about 50 to about 5000.

The linear supporter 38 is configured for supporting the heating element 36 and the heat-reflecting layer 37. The linear supporter 38 has a linear structure, and the diameter of the linear supporter 38 is small compared with a length of the linear supporter 38. Other characters of the linear supporter 38 can be the same as the planar supporter 18 as disclosed herein.

The heating element 36 can be attached on the surface of the linear supporter 38 directly. When the heat-reflecting layer 37 wraps on the surface of the linear supporter 38, the heating element 36 can be attached on the surface of the heat-reflecting layer 37. The same as the heating element 16 in the first embodiment, the heating element 36 includes a carbon nanotube structure. The characters of the carbon nanotube structure can be the same as the carbon nanotube structure discussed above.

The first electrode 32 and the second electrode 34 can be disposed on a same surface or opposite surfaces of the heating element 36. The shape of the first electrode 32 or the second electrode 34 is not limited and can be lamellar, rod, wire, and block among other shapes. In the embodiment shown in FIGS. 15 and 16, the first electrode 32 and the second electrode 34 are both lamellar rings. In some embodiments, the carbon nanotubes in the heating element 36 are aligned along a direction perpendicular to the first electrode 32 and the second electrode 34. In other embodiments, at least one of the first electrode 32 and the second electrode 34 includes at least one carbon nanotube film or at least a linear carbon nanotube structure. In other embodiments, each of the first electrode 32 and the second electrode 34 includes a linear carbon nanotube structure. The linear carbon nanotube structures disposed on the two ends of the heating element 36, and wrap the heating element 36 to form two rings.

The protecting layer 35 is disposed on the outer surface of the heating element 36. In one embodiment, the protecting layer 35 fully covers the outer surface of the heating element 36. The heating element 36 is located between the protecting layer 35 and the heat-reflecting layer 37.

In use of the linear heater 30, the heater 30 can be twisted about a target like a helix, and the target will be heated from outside. The heater 30 can also be inserted into the target to heat the target form inside. Given the small size of the linear heater 30, it can be used in applications with limited space or in the field of MEMS for example.

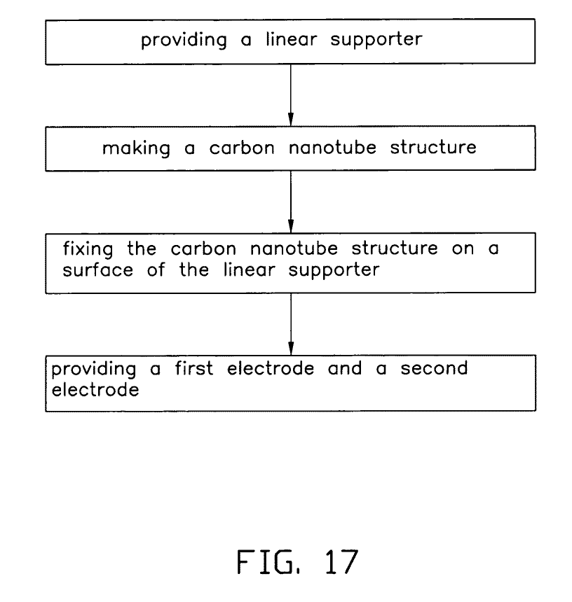

Referring FIG. 17, a method for making a linear heater 30 is provided. The method includes the steps of:

N1: providing a linear supporter 38;

N2: making a carbon nanotube structure;

N3: fixing the carbon nanotube structure on a surface of the linear supporter 38; and

N4: providing a first electrode 32 and a second electrode 34.

It is to be understood that, before step N3, additional steps of forming a reflecting layer 37 on the linear supporter 38 can be further processed. After step N4, an additional step of forming a protecting layer 35 on the heating element 36, the first electrode 32 and the second electrode 34 can be further processed.

In step N2, the detailed process of making the carbon nanotube structure can be the same as the step S2 discussed above.

In step N3, the carbon nanotube structure can be fixed on the surface of the linear supporter 38 with an adhesive or by mechanical method. In some embodiments, the carbon nanotube structure can be directly adhered on the linear supporter because of the adhesive nature of the carbon nanotube structure. The carbon nanotube structure can wrap the surface of the linear supporter 38. When the carbon nanotube structure includes a plurality of carbon nanotubes substantially oriented along a same direction, the oriented direction can be from one end of the supporter 38 to another end of the supporter 38.

The detail process of the step N4 can be the same as the step S4 discussed above.

It is to be understood that the above-described embodiments are intended to illustrate rather than limit the invention. Variations may be made to the embodiments without departing from the spirit of the invention as claimed. It is understood that any element of any one embodiment is considered to be disclosed to be incorporated with any other embodiment. The above-described embodiments illustrate the scope of the invention but do not restrict the scope of the invention.

It is also to be understood that above description and the claims drawn to a method may include some indication in reference to certain steps. However, the indication used is only to be viewed for identification purposes and not as a suggestion as to an order for the steps.

What claimed is:

1. A method of making a heater, the method comprising the following steps:
making a carbon nanotube structure;
providing a first electrode and a second electrode; and
electrically connecting the first and second electrodes to the carbon nanotube structure.

2. The method of claim 1, wherein the carbon nanotube structure comprises at least a carbon nanotube film, at least a linear carbon nanotube structure or a combination thereof.

3. The method of claim 1, wherein the step of method for making the carbon nanotube structure comprises the following sub-steps:
providing an array of carbon nanotubes, and
drawing a carbon nanotube film from the carbon nanotube array.

4. The method of claim 3, wherein the step of drawing the carbon nanotube film comprised of the following sub-steps of:
selecting one or more carbon nanotubes having a predetermined width from the array of carbon nanotubes; and
pulling the carbon nanotubes to form nanotube segment at an uniform speed to achieve a carbon nanotube film.

5. The method of claim 4, wherein the carbon nanotubes are selected by using an adhesive tape to contact the array of carbon nanotubes.

6. The method of claim 4, wherein the pulling direction is substantially perpendicular to a growing direction of the array of carbon nanotubes.

7. The method of claim 1, wherein the step of making a carbon nanotube structure comprises a step of treating a carbon nanotube film with an organic solvent.

8. The method of claim 1, wherein the step of making the carbon nanotube film comprises the sub-steps of:
providing a carbon nanotube array and a pressing device, the carbon nanotube array comprises a plurality of carbon nanotubes; and
pressing the carbon nanotube array with the pressing device.

9. The method of claim 8, wherein the step of pressing the carbon nanotube array comprises the sub-steps of :
proving a planar pressure head; and
using the planar press head to press the carbon nanotubes in the carbon nanotube array;
wherein the resulting carbon nanotube film is isotropic.

10. The method of claim 8, wherein the step of pressing the carbon nanotube array comprises the sub-steps of:
providing a roller-shaped pressure head, and
rolling the roller-shaped pressure head on the carbon nanotube array along a certain direction.

11. The method of claim 2, wherein the step of method for making the carbon nanotube film comprises the following sub-steps:
providing an array of carbon nanotubes;
separating the array of carbon nanotubes from the substrate to get a plurality of carbon nanotubes;
adding the plurality of carbon nanotubes to a solvent; and
separating a carbon nanotube floccule structure from the solvent.

12. The method of claim 11, wherein the step of separating the carbon nanotube floccule structure from the solvent comprises the sub-steps of:
filtering out the solvent to obtain the carbon nanotube floccule structure; and
drying the carbon nanotube floccule structure to obtain the separated carbon nanotube floccule structure.

13. The method of claim 11, further comprising the step of shaping the carbon nanotube floccule structure comprises the following sub-steps:
putting the separated carbon nanotube floccule structure into a container, and spreading the carbon nanotube floccule structure to form a predetermined structure; and
pressing the spread carbon nanotube floccule structure to yield a desirable shape.

14. The method of claim 2, wherein the linear carbon nanotube structure comprises a carbon nanotube wire, and the method for making the carbon nanotube wire comprises the steps of:
providing an array of carbon nanotubes;
pulling out at least a carbon nanotube film from the carbon nanotube array; and
treating the carbon nanotube film with an organic solvent or with a mechanical force to form a carbon nanotube wire.

15. The method of claim 2, the linear carbon nanotube structure comprises a carbon nanotube cable, and the carbon nanotube cable is formed by a step of bundling two or more carbon nanotube wires together by an adhesive or a mechanical force.

16. The method of claim 1, further comprising a step of forming a heat-reflecting layer by coating method, chemical deposition method or ion sputtering method.

17. The method of claim 1, further comprising a step of forming a protecting layer to cover the carbon nanotube structure by coating method or sputtering method.

18. A method for making a planar heater, the method comprising the following steps:
providing a planar supporter, a first electrode and a second electrode;
making a carbon nanotube structure;
fixing the carbon nanotube structure on a surface of the planar supporter; and
electrically connecting the first and second electrodes to the carbon nanotube structure.

19. The method of claim 18, wherein the carbon nanotube structure is fixed on the surface of the planar supporter with an adhesive or by a mechanical force.

20. The method of claim 18, wherein the carbon nanotube structure comprises a plurality of carbon nanotubes combined by van der Waals force.
